(19) United States
(12) Patent Application Publication
(10) Pub. No.: US 2026/0259070 A1
(43) Pub. Date: Sep. 3, 2026

(54) Quantum Sensor System Configured to Determine a Measurement of a Physical Condition

(71) Applicant: Toyota Motor Engineering & Manufacturing North America, Inc., Plano, TX (US)

(72) Inventors: Paul Donald SCHMALENBERG, Ann Arbor, MI (US); Ercan Mehmet DEDE, Ann Arbor, MI (US)

(73) Assignee: Toyota Motor Engineering & Manufacturing North America, Inc., Plano, TX (US)

(21) Appl. No.: 19/045,997

(22) Filed: Feb. 5, 2025

(51) Int. Cl. G01D 21/02

(52) U.S. Cl. CPC G01D 21/02

(57) ABSTRACT

An apparatus for determining a measurement of a physical condition can include a light-emitting diode, an antenna, a quantum material, a photodetector, and a transparent material interface. The antenna can be configured to emit an electromagnetic signal that sweeps through a range of frequencies. The photodetector can be configured to determine an amplitude of a wavelength of a light emitted by the quantum material. The amplitude can be a function of a frequency, within the range, and the measurement of the physical condition. The transparent material interface can be made of a transparent epoxy and can be configured to convey the light: (1) from the light-emitting diode to the quantum material and (2) from the quantum material to the photodetector.

### TECHNICAL FIELD

The disclosed technologies are directed to determining a measurement of a physical condition.

### BACKGROUND

A sensor can be a device used to detect or measure a physical condition. Because of this ability to detect or measure a physical condition, a sensor can be used in a control system configured to control an operation of a machine. In order to improve a performance of such a control system, it can be desirable both to reduce a size of a sensor, so that the sensor can be disposed in close proximity to the physical condition to be detected or measured, and to increase a degree of sensitivity of the sensor with respect to changes in the physical condition to be detected or measured. Micro-electromechanical systems (MEMS) and micro-opto-electromechanical systems (MOEMS) technologies can facilitate manufacturing such small-sized sensors. Additionally, quantum sensor technologies can facilitate designing sensors having a high degree of sensitivity. A quantum sensor can be configured to detect or measure a physical condition based on a quantum mechanical property of a material from which the quantum sensor is made. Such quantum mechanical properties can include, for example, spin-state quantum entanglement, quantum interference, quantum state squeezing, or the like. Certain materials have properties that cannot be described in terms associated classical physics or low-level quantum mechanics and that can lend themselves to being used to detect or measure a physical condition with a high degree of sensitivity. Such materials can be referred to as quantum materials. Typically, a quantum sensor can include a quantum material.

### SUMMARY

In an embodiment, an apparatus for determining a measurement of a physical condition can include a light-emitting diode, an antenna, a quantum material, a photodetector, and a transparent material interface. The antenna can be configured to emit an electromagnetic signal that sweeps through a range of frequencies. The photodetector can be configured to determine an amplitude of a wavelength of a light emitted by the quantum material. The amplitude can be a function of a frequency, within the range, and the measurement of the physical condition. The transparent material interface can be made of a transparent epoxy and can be configured to convey the light: (1) from the light-emitting diode to the quantum material and (2) from the quantum material to the photodetector.

In another embodiment, an apparatus for determining a measurement of a physical condition can include a first integrated circuit, an antenna, a quantum material, and a second integrated circuit. The first integrated circuit can be attached to a substrate and can include a light-emitting diode. The antenna can be attached to the substrate and can be configured to emit an electromagnetic signal that sweeps through a range of frequencies. The second integrated circuit can be attached to the substrate and can include a photodetector configured to determine an amplitude of a wavelength of a light emitted by the quantum material. The amplitude can be a function of a frequency, within the range, and the measurement of the physical condition.

In another embodiment, an array of sensors can include a first set of sensors and a second set of sensors. Each sensor of the first set of sensors can: (1) have a light-emitting diode, an antenna, a quantum material, and a photodetector and (2) be configured to determine a measurement of a first physical condition. Each sensor of the second set of sensors can: (1) have a light-emitting diode, an antenna, a quantum material, and a photodetector and (2) be configured to determine a measurement of a second physical condition.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 includes a graph of an example of fluorescence intensity as a function of frequency for a wavelength of a light emitted by a quantum material when a measurement of a physical condition has a first value.

FIG. 2 includes a graph of an example of fluorescence intensity as a function of frequency for the wavelength of the light emitted by the quantum material when the measurement of the physical condition has a second value.

FIG. 3 includes a diagram that illustrates a first example of an apparatus for determining a measurement of a physical condition, according to the disclosed technologies.

FIG. 4 includes a diagram that illustrates a second example of the apparatus for determining the measurement of the physical condition, according to the disclosed technologies.

FIG. 5 includes a diagram that illustrates a third example of the apparatus for determining the measurement of the physical condition, according to the disclosed technologies.

FIG. 6 includes a diagram that illustrates a fourth example of the apparatus for determining the measurement of the physical condition, according to the disclosed technologies.

FIG. 7 includes a diagram that illustrates the evolution of packaging technologies.

FIG. 8 includes a diagram that illustrates a roadmap of the development of packaging technologies.

FIG. 9 includes a diagram that illustrates an example of an array of sensors, according to the disclosed technologies.

FIG. 10 includes a diagram that illustrates a first example of a system-on-a-chip package of the array of sensors, according to the disclosed technologies.

FIG. 11 includes a diagram that illustrates a second example of the system-on-a-chip package of the array of sensors, according to the disclosed technologies.

FIG. 12 includes a diagram that illustrates an example of positions, on a head, at which measures of electrical activity of a brain are obtained for an electroencephalogram.

FIG. 13 includes a diagram that illustrates an example of the array of sensors disposed upon a car seat, according to the disclosed technologies.

FIG. 14 includes a diagram that illustrates an example of the array of sensors disposed upon a surface of a pouch cell, according to the disclosed technologies.

### DETAILED DESCRIPTION

The disclosed technologies are directed to determining a measurement of a physical condition. For example, an apparatus for determining a measurement of a physical condition can include a light-emitting diode, an antenna, a quantum material, and a photodetector. The antenna can be configured to emit an electromagnetic signal that sweeps through a range of frequencies. For example, the range of the frequencies can include a range within a microwave frequency range of the electromagnetic spectrum. The photodetector can be configured to determine an amplitude of a wavelength of a light emitted by the quantum material. The amplitude can be a function of a frequency, within the range, and the measurement of the physical condition.

For example, the physical condition can include one or more of a strength of a magnetic field in an environment of the apparatus, a temperature of the environment, a mechanical strain of an object in the environment, or the like. For example, the apparatus can include a magnetic field strain gauge configured to measure the mechanical strain as a function of the magnetic field associated with the object.

For example, the wavelength of the light emitted by the quantum material can be a first wavelength. For example, the first wavelength can be associated with a red color. For example, a wavelength of the light produced by the light-emitting diode can be a second wavelength. For example, the second wavelength can be associated with a green color. For example, reception, by the quantum material, of the light at the second wavelength can cause the quantum material to emit the light at the first wavelength. For example, the amplitude of the first wavelength of the light can be characterized by minima values of fluorescence intensity at specific frequencies within the range of frequencies. For example, the specific frequencies can include a first set of specific frequencies and a second set of specific frequencies. For example, specific frequencies in the first set of frequencies can be greater than a center frequency of the range. For example, the center frequency can be 2.87 gigahertz. For example, specific frequencies in the second set of frequencies can be less than the center frequency. For example, an absolute value of a difference between the center frequency and a particular frequency of the first set can be equal to an absolute value of a difference between the center frequency and a corresponding particular frequency of the second set. For example, an absolute value of a difference between the particular frequency and the corresponding particular frequency can be proportional to the measurement of the physical condition. For example, a purpose of a sweep through the range of frequencies can be to identify the specific frequencies.

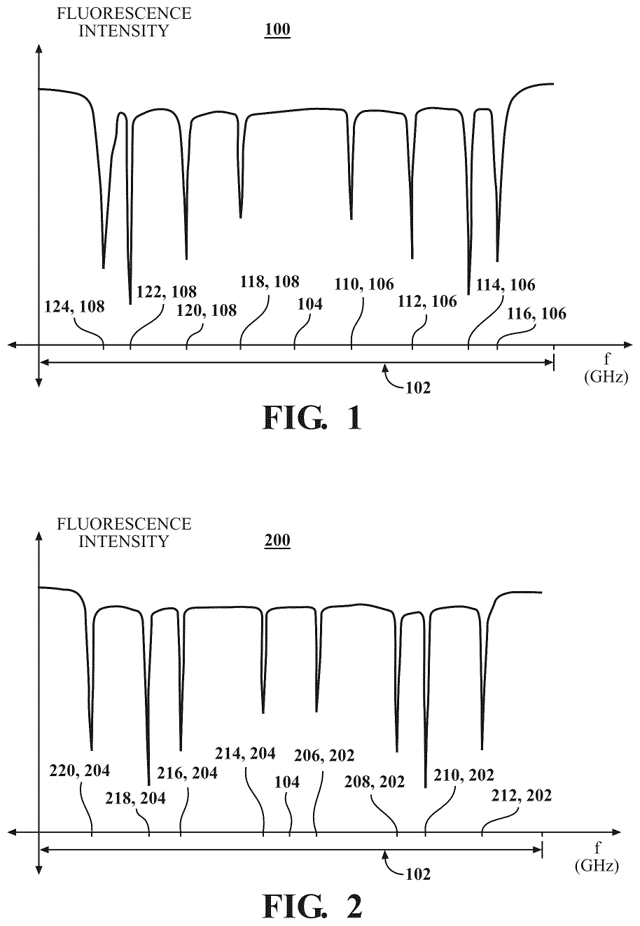

FIG. 1 includes a graph 100 of an example of fluorescence intensity as a function of frequency for a wavelength of a light emitted by a quantum material when a measurement of a physical condition has a first value. For example, the graph 100 can include a range 102 of frequencies. For example, the range 102 can include a center frequency 104. For example, the graph 100 can include a first set 106 of specific frequencies and a second set 108 of specific frequencies. For example, the first set 106 of specific frequencies can be greater than the center frequency 104. For example, the first set 106 of specific frequencies can include a first frequency 110, a second frequency 112, a third frequency 114, and a fourth frequency 116. For example, the second set 108 of specific frequencies can be lesser than the center frequency 104. For example, the second set 108 of specific frequencies can include a first frequency 118, a second frequency 120, a third frequency 122, and a fourth frequency 124.

For example, an absolute value of a difference between the center frequency 104 and a particular frequency of the first set 106 can be equal to an absolute value of a difference between the center frequency 104 and a corresponding particular frequency of the second set 108. For example: (1) the absolute value of the difference between the center frequency 104 and the first frequency 110 can be equal to the absolute value of the difference between the center frequency 104 and the first frequency 118, (2) the absolute value of the difference between the center frequency 104 and the second frequency 112 can be equal to the absolute value of the difference between the center frequency 104 and the second frequency 120, (3) the absolute value of the difference between the center frequency 104 and the third frequency 114 can be equal to the absolute value of the difference between the center frequency 104 and the third frequency 122, and (4) the absolute value of the difference between the center frequency 104 and the fourth frequency 116 can be equal to the absolute value of the difference between the center frequency 104 and the fourth frequency 124. For example, an absolute value of a difference between the particular frequency and the corresponding particular frequency can be proportional to the measurement of the physical condition. For example, the absolute value of the difference between the first frequency 110 and the first frequency 118 can be proportional to the first value of the measurement of the physical condition.

FIG. 2 includes a graph 200 of an example of fluorescence intensity as a function of frequency for the wavelength of the light emitted by the quantum material when the measurement of the physical condition has a second value. For example, the graph 200 can include the range 102 of frequencies. For example, the range 102 can include the center frequency 104. For example, the graph 200 can include a first set 202 of specific frequencies and a second set 204 of specific frequencies. For example, the first set 202 of specific frequencies can be greater than the center frequency 104. For example, the first set 202 of specific frequencies can include a first frequency 206, a second frequency 208, a third frequency 210, and a fourth frequency 212. For example, the second set 204 of specific frequencies can be lesser than the center frequency 104. For example, the second set 204 of specific frequencies can include a first frequency 214, a second frequency 216, a third frequency 218, and a fourth frequency 220.

For example, an absolute value of a difference between the center frequency 104 and a particular frequency of the first set 202 can be equal to an absolute value of a difference between the center frequency 104 and a corresponding particular frequency of the second set 204. For example: (1) the absolute value of the difference between the center frequency 104 and the first frequency 206 can be equal to the absolute value of the difference between the center frequency 104 and the first frequency 214, (2) the absolute value of the difference between the center frequency 104 and the second frequency 208 can be equal to the absolute value of the difference between the center frequency 104 and the second frequency 216, (3) the absolute value of the difference between the center frequency 104 and the third frequency 210 can be equal to the absolute value of the difference between the center frequency 104 and the third frequency 218, and (4) the absolute value of the difference between the center frequency 104 and the fourth frequency 212 can be equal to the absolute value of the difference between the center frequency 104 and the fourth frequency 220. For example, an absolute value of a difference between the particular frequency and the corresponding particular frequency can be proportional to the measurement of the physical condition. For example, the absolute value of the difference between the first frequency 206 and the first frequency 214 can be proportional to the second value of the measurement of the physical condition.

Although micro-opto-electromechanical systems (MOEMS) technologies can facilitate manufacturing an apparatus for determining a measurement of a physical condition, because such an apparatus can incorporate various aspects of optics technologies and electronics technologies and because the electronics technologies can be associated with devices configured to operate within a microwave frequency range of the electromagnetic spectrum, manufacturing such an apparatus can be a complex undertaking that involves a wide variety of materials. The disclosed technologies include various techniques to simplify the manufacture of an apparatus for determining a measurement of a physical condition.

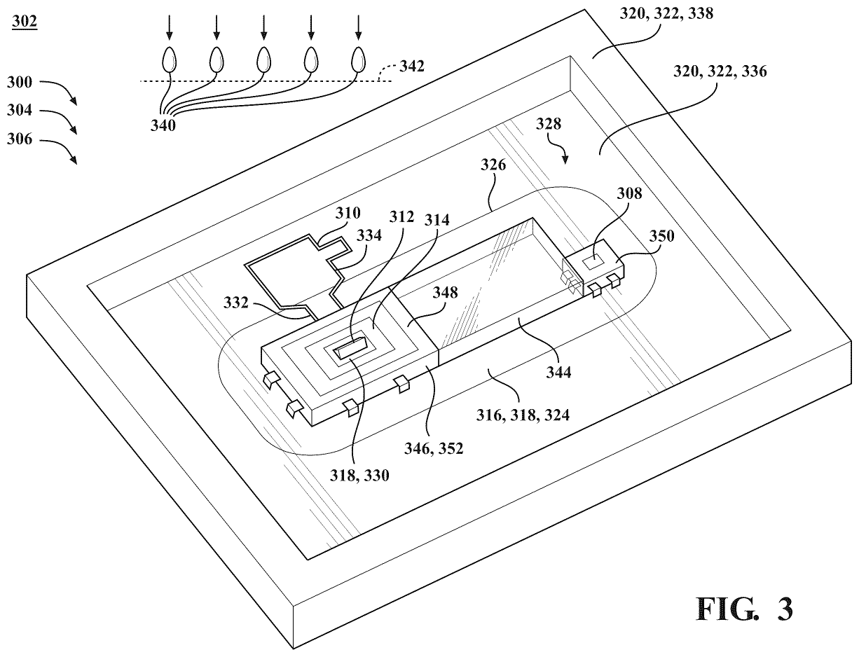

FIG. 3 includes a diagram that illustrates a first example 302 of an apparatus 300 for determining a measurement of a physical condition, according to the disclosed technologies. The first example 302 can be a first variation 304 of a first implementation 306 of the disclosed technologies. In the first example 302, the apparatus 300 can include a light-emitting diode 308, an antenna 310, a quantum material 312, a photodetector 314, and a transparent material interface 316. For example, the antenna 310 can be configured to emit an electromagnetic signal that sweeps through a range of frequencies. For example, the photodetector 314 can be configured to determine an amplitude of a wavelength of a light emitted by the quantum material 312. For example, the amplitude can be a function of a frequency, within the range, and the measurement of the physical condition. For example, the transparent material interface 316 can be made of a transparent epoxy 318 and can be configured to convey the light: (1) from the light-emitting diode 308 to the quantum material 312 and (2) from the quantum material 312 to the photodetector 314.

Additionally, in a specific realization 320 of the first implementation 306, the apparatus 300 can include a substrate 322. For example, the light-emitting diode 308, the antenna 310, and the photodetector 314 can be attached to the substrate 322. For example, at least a portion 324 of the transparent epoxy 318 can form the transparent material interface 316 defined by a two-dimensional closed curve 326 on a plane 328 of the substrate 322. For example, using the transparent epoxy 318 to form the transparent material interface 316 can simplify the manufacture of the apparatus 300. Additionally, in the first variation 304 of the specific realization 320 of the first implementation 306, the quantum material 312 can be attached to the photodetector 314 by another portion 330 of the transparent epoxy 318.

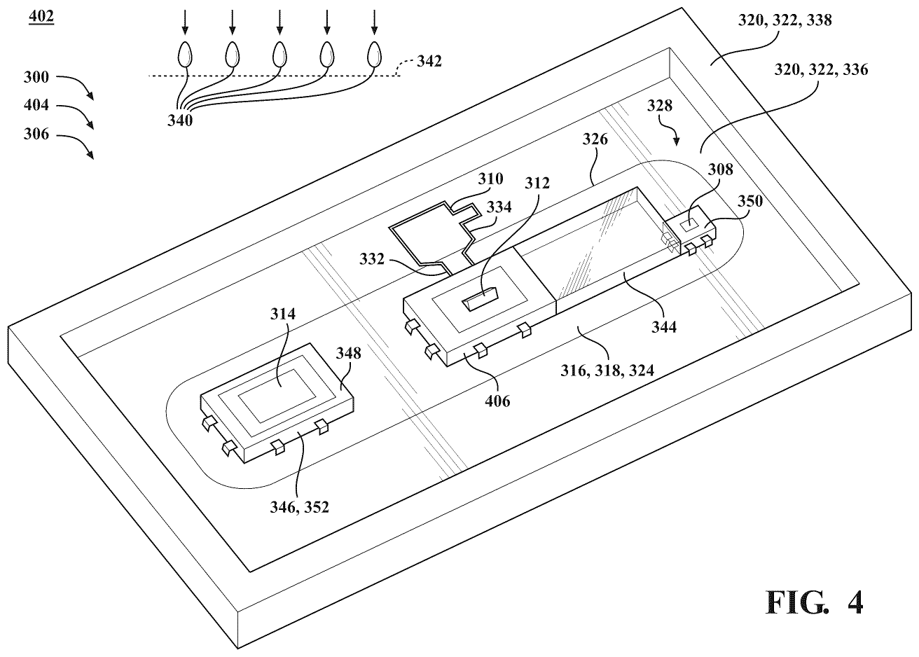

FIG. 4 includes a diagram that illustrates a second example 402 of the apparatus 300 for determining the measurement of the physical condition, according to the disclosed technologies. The second example 402 can be a second variation 404 of the first implementation 306 of the disclosed technologies. In the second example 402, the apparatus 300 can include the light-emitting diode 308, the antenna 310, the quantum material 312, the photodetector 314, and the transparent material interface 316. For example, the antenna 310 can be configured to emit the electromagnetic signal that sweeps through the range of frequencies. For example, the photodetector 314 can be configured to determine the amplitude of the wavelength of the light emitted by the quantum material 312. For example, the amplitude can be the function of the frequency, within the range, and the measurement of the physical condition. For example, the transparent material interface 316 can be made of a transparent epoxy 318 and can be configured to convey the light: (1) from the light-emitting diode 308 to the quantum material 312 and (2) from the quantum material 312 to the photodetector 314.

Additionally, in the specific realization 320 of the first implementation 306, the apparatus 300 can include the substrate 322. For example, the light-emitting diode 308, the antenna 310, and the photodetector 314 can be attached to the substrate 322. For example, the at least the portion 324 of the transparent epoxy 318 can form the transparent material interface 316 defined by the two-dimensional closed curve 326 on the plane 328 of the substrate 322. For example, using the transparent epoxy 318 to form the transparent material interface 316 can simplify the manufacture of the apparatus 300. Additionally, in the second variation 404 of the specific realization 320 of the first implementation 306, the quantum material 312 can be attached to the substrate 322 and can be disposed between the light-emitting diode 308 and the photodetector 314.

With references to FIGS. 3 and 4, additionally, for example, the light-emitting diode 308 can include a micro light-emitting diode. For example, the micro light-emitting diode can include a quantum dot.

Additionally, for example, in the first implementation 306, the antenna 310 can include a line antenna.

Additionally, for example, the quantum material 312 can include one of a diamond having a nitrogen-vacancy center, boron nitride, or silicon carbide.

Additionally, for example: (1) the wavelength of the light emitted by the quantum material 312 can be associated with a red color and (2) a wavelength of the light produced by the light-emitting diode 308 can be associated with a green color.

Additionally, for example, the photodetector 314 can include a photodiode. Additionally or alternatively, the photodetector 314 can include an array of photodetectors.

Additionally, for example, in the specific realization 320 of the first implementation 306: (1) a first portion 332 of the antenna 310 can be in proximity to the quantum material 312 and can be inside of the two-dimensional closed curve 326 and (2) a second portion 334 of the antenna 310 can be outside of the two-dimensional closed curve 326.

Additionally, for example, in the specific realization 320 of the first implementation 306: (1) the substrate 322 can include a semiconductor chip 336 with sidewalls 338 and (2) the apparatus 300 can further include an opaque epoxy 340 deposited on the semiconductor chip 336 in a manner that forms a light confinement system 342 configured to keep the light within the apparatus 300.

Additionally, for example, in the specific realization 320 of the first implementation 306, the apparatus 300 can further include a light pipe 344 disposed between the light-emitting diode 308 and the quantum material 312 and configured to convey the light from the light-emitting diode 308 to the quantum material 312. For example: (1) a material from which an interior of the light pipe 344 can be made can have a first refractive index and (2) a material from which an exterior of the light pipe 344 can be made can have a second refractive index. For example, the light-emitting diode 308, the light pipe 344, and the quantum material 312 can be configured so that paths of the light from the light-emitting diode 308 to the quantum material 312 remain within the interior of the light pipe 344. For example, a configuration of the light-emitting diode 308, the light pipe 344, and the quantum material 312 can be based on Brewster's angle. For example, the material from which the interior of the light pipe 344 can be made can include one or more of silicon, silica, or plastic. Additionally, for example: (1) the substrate 322 can include the semiconductor chip 336 with the sidewalls 338 and (2) the apparatus 300 can further include the opaque epoxy 340 deposited on the semiconductor chip 336 in the manner that forms the light confinement system 342 configured to keep the light within the apparatus 300.

Additionally, for example, in the first implementation 306, the photodetector 314 can be included in an integrated circuit 346. For example, the integrated circuit 346 can further include a filter 348. For example, the filter 348 can be disposed between the quantum material 312 and the photodetector 314 and can be configured to filter a wavelength of the light produced by the light-emitting diode 308.

Additionally, for example, in the first implementation 306: (1) the light-emitting diode 308 can be included in a first integrated circuit 350, (2) the photodetector 314 can be included in a second integrated circuit 352, and (3) the apparatus 300 can further include the substrate 322 to which the first integrated circuit 350 and the second integrated circuit 352 can be attached. For example, including the light-emitting diode 308 in the first integrated circuit 350 and the photodetector 314 included in the second integrated circuit 352 can simplify the manufacture of the apparatus 300. Additionally, for example, in the second variation 404 of the first implementation 306, the quantum material 312 can be included in a third integrated circuit 406. For example, the third integrated circuit 406 can be attached to the substrate 322. For example, including the quantum material 312 in the third integrated circuit 406 can simplify the manufacture of the apparatus 300.

For example, one or more of the integrated circuit 346, the first integrated circuit 350, the second integrated circuit 352, or the third integrated circuit 406 can be included in a surface-mount integrated circuit package. For example, the surface-mount integrated circuit package can be a flat no-leads package. For example, a flat no-leads package can connect an integrated circuit to a printed circuit board without through-holes, which can simplify the manufacture of the apparatus 300. For example, a flat no-leads package can encapsulate the integrated circuit in a plastic and can include a planar-shaped conductive lead frame substrate. For example, one or more bond wires can connect the integrated circuit to the planar-shaped conductive lead frame substrate. For example, lands on a perimeter of the planar-shaped conductive lead frame substrate can provide an electrical connection to the printed circuit board. For example, the planar-shaped conductive lead frame substrate can be soldered to the printed circuit board. For example, the planar-shaped conductive lead frame substrate can be made of copper. Additionally, for example, a flat no-leads package can include a thermal conductive pad to facilitate removal of heat from the integrated circuit. Advantageously, for example, a flat no-leads package can have a thin profile and a small form factor. Advantageously, for example, a measurement of an inductance of the planar-shaped conductive lead frame can be low. For example, the flat no-leads package can be a dual-flat no-leads package, a quad-flat no-leads (QFN) package, or the like.

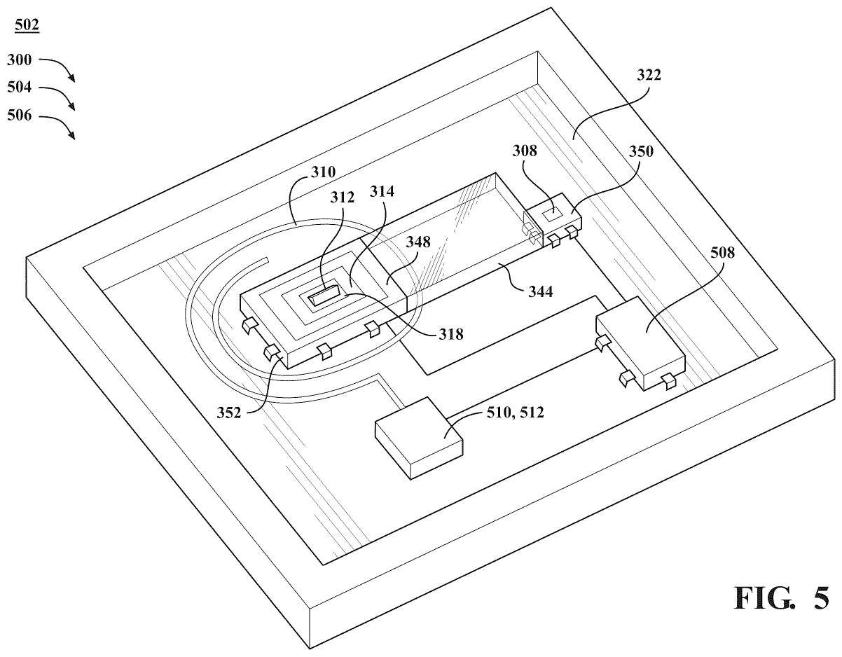

FIG. 5 includes a diagram that illustrates a third example 502 of the apparatus 300 for determining the measurement of the physical condition, according to the disclosed technologies. The third example 502 can be a first variation 504 of a second implementation 506 of the disclosed technologies. In the third example 502, the apparatus 300 can include the first integrated circuit 350, the antenna 310, the quantum material 312, and the second integrated circuit 352. For example, the first integrated circuit 350 can be attached to the substrate 322 and can include the light-emitting diode 308. For example, the antenna 310 can be attached to the substrate 322 and can be configured to receive the electromagnetic signal that sweeps through the range of frequencies. For example, the second integrated circuit 352 can be attached to the substrate 322 and can include the photodetector 314 configured to determine the amplitude of the wavelength of the light emitted by the quantum material 312. For example, including the light-emitting diode 308 in the first integrated circuit 350 and the photodetector 314 included in the second integrated circuit 352 can simplify the manufacture of the apparatus 300. Additionally, in the first variation 504 of the second implementation 506, the quantum material 312 can be attached to the photodetector 314 by the transparent epoxy 318.

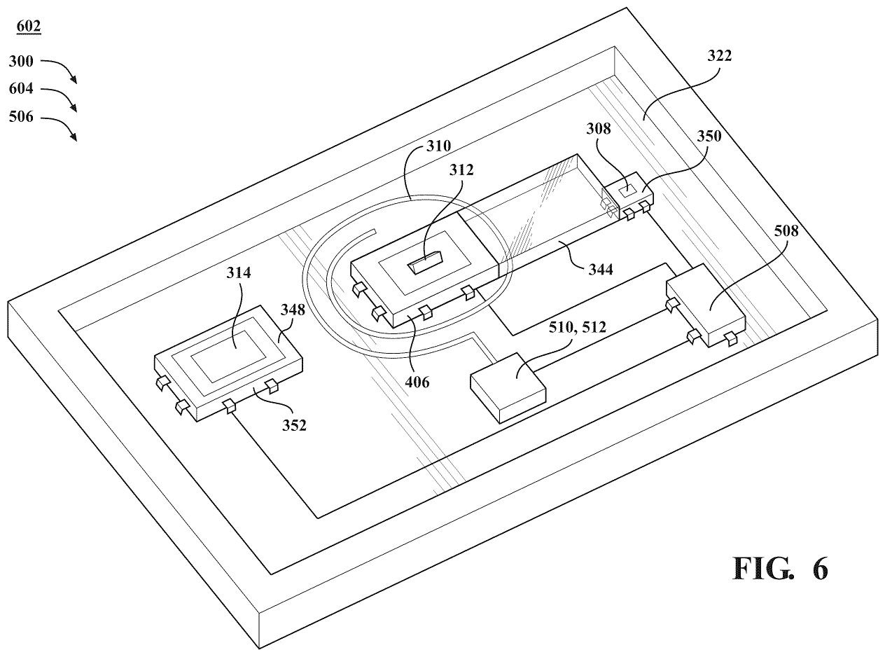

FIG. 6 includes a diagram that illustrates a fourth example 602 of the apparatus 300 for determining the measurement of the physical condition, according to the disclosed technologies. The fourth example 602 can be a second variation 604 of the second implementation 506 of the disclosed technologies. In the fourth example 602, the apparatus 300 can include the first integrated circuit 350, the antenna 310, the quantum material 312, and the second integrated circuit 352. For example, the first integrated circuit 350 can be attached to the substrate 322 and can include the light-emitting diode 308. For example, the antenna 310 can be attached to the substrate 322 and can be configured to receive the electromagnetic signal that sweeps through the range of frequencies. For example, the second integrated circuit 352 can be attached to the substrate 322 and can include the photodetector 314 configured to determine the amplitude of the wavelength of the light emitted by the quantum material 312. For example, including the light-emitting diode 308 in the first integrated circuit 350 and the photodetector 314 included in the second integrated circuit 352 can simplify the manufacture of the apparatus 300. Additionally, in the second variation 604 of the second implementation 506, the quantum material 312 can be included in the third integrated circuit 406. For example, the third integrated circuit 406 can be attached to the substrate 322. For example, including the quantum material 312 in the third integrated circuit 406 can simplify the manufacture of the apparatus 300.

With references to FIGS. 5 and 6, additionally, for example, in the second implementation 506, the antenna 310 can have a spiral shape and can surround the quantum material 312.

Additionally, for example, in the second implementation 506, the second integrated circuit 352 can further include the filter 348. For example, the filter 348 can be disposed between the quantum material 312 and the photodetector 314 and can be configured to filter the wavelength of the light produced by the light-emitting diode 308.

Additionally, for example, in the second implementation 506, the apparatus 300 can further include the light pipe 344 disposed between the light-emitting diode 308 and the quantum material 312 and configured to convey the light from the light-emitting diode 308 to the quantum material 312.

Additionally, for example, in the second implementation 506, the apparatus 300 can further include a controller 508. For example, the controller 508 can be attached to the substrate 322. For example, the controller 508 can be electronically communicably coupled to the first integrated circuit 350 and the second integrated circuit 352. For example, the controller 508 can be configured to control an operation of the light-emitting diode 308 and to determine the measurement of the physical condition.

Additionally, in a specific realization 510 of the second implementation 506, the apparatus 300 can further include a microwave source 512. For example, the microwave source 512 can be attached to the substrate 322. For example, the microwave source 512 can be electronically communicably coupled to the controller 508. For example, the microwave source 512 can be configured to produce the electromagnetic signal. For example, the controller 508 can be further configured to cause the microwave source 512 to produce the electromagnetic signal in the manner that includes the sweep through the range of frequencies.

Because the apparatus 300 can include, for example, several devices that perform different functions but are all attached to the substrate 322, the apparatus 300 itself can be an integrated circuit and can be referred to as a system-on-a-chip (SoC). Additionally, for example, the apparatus 300 can include an SoC package that includes the several devices that perform the different functions but are all attached to the substrate 322. For example, the SoC package can be configured to be mounted to another substrate (not illustrated) or a printed circuit board (not illustrated).

An SoC package can be classified, for example, based on: (1) the way in which leads are arranged on the SoC package, (2) the way in which the leads are mounted on a printed circuit board, or (3) a material used for the SoC package. For example, a classification of an SoC package based on the way in which the leads are arranged on the SoC package can include: (1) in-line, (2) periphery, or (3) array. For example, a classification of an SoC package based on the way in which the leads are arranged on the SoC package can include: (1) through hole or (2) surface mount. For example, a classification of an SoC package based on the material used for the SoC package can include: (1) ceramic or (2) plastic. Additionally, a ceramic SoC package can be further classified, for example, as: (1) military, (2) automotive, or (3) space; and a plastic SoC package can be further classified as: (1) industrial or (2) commercial. Moreover, SoC package technology can include, for example: (1) wire bonded, (2) flip-chip, and (3) advanced. For example, wire bonded SoC package technology can include Quad Flat Package, Ball Grid Array, etc. For example, flip-chip SoC package technology can include Fine Pitch Ball Grid Array, etc. For example, advanced SoC package technology can include system-in-package (SiP), chip-scale package (CSP), wafer-level package (WLP), etc.

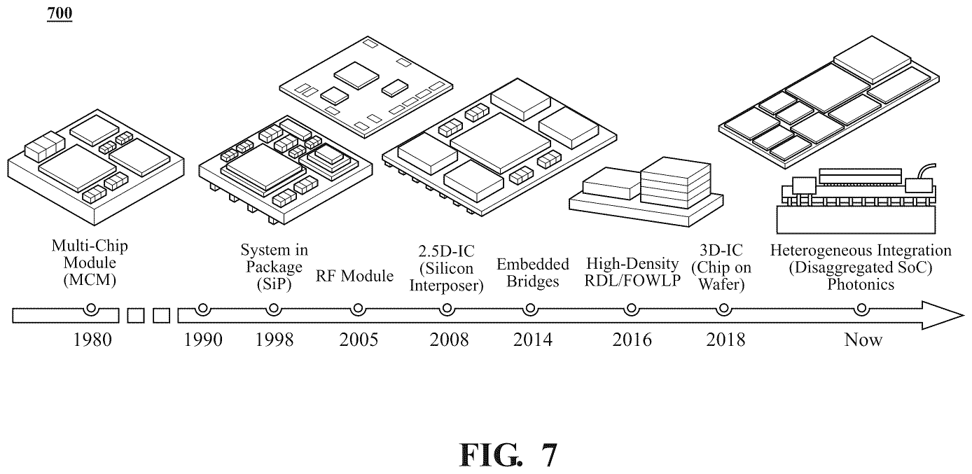

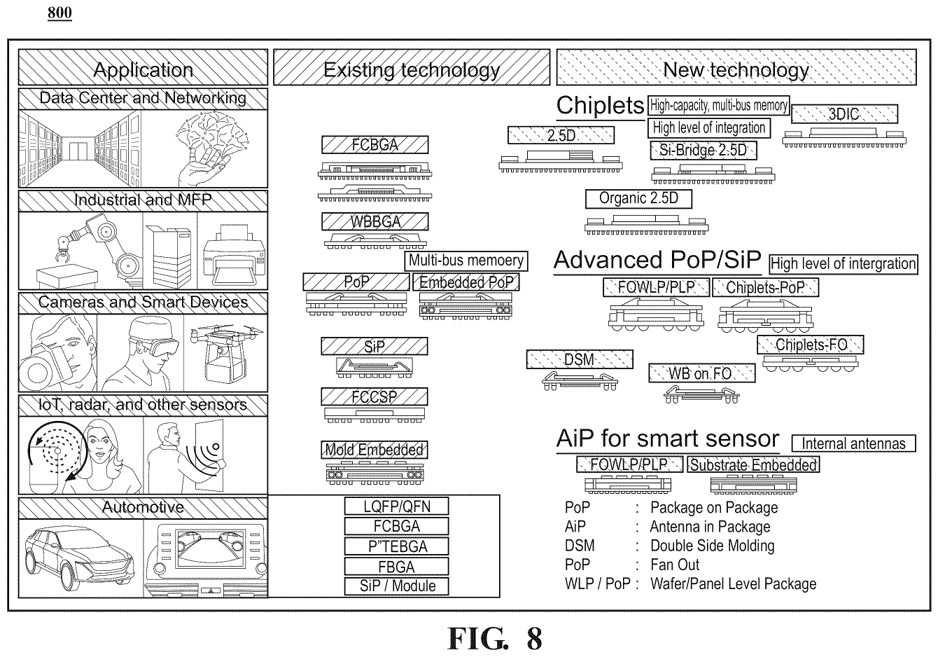

FIG. 7 includes a diagram 700 that illustrates the evolution of packaging technologies. FIG. 8 includes a diagram 800 that illustrates a roadmap of the development of packaging technologies. The packaging technologies illustrated in the diagram 700 include multi-chip module (MCM) packaging technology, system-in-package (SiP) packaging technology, radio frequency (RF) module packaging technology, 2.5D integrated circuit (2.5D IC) packaging technology (also referred to as silicon interposer packaging technology), embedded bridges packaging technology, high-density redistribution layer/fan-out wafer-level packaging (RDL/FOWLP) technology, three-dimensional integrated circuit (3D IC) packaging technology (also referred to as chip-on-wafer packaging technology), and heterogenous integration (HI) packaging technology (also referred to as disaggregated SoC packaging technology). The packaging technologies illustrated in the diagram 800 can support multifunction printer (MFP) applications and Internet of things (IoT) applications. The packaging technologies illustrated in the diagram 800 include flip-chip ball grid array (FCBGA) packaging technology, wire bond ball grid array (WBBGA) packaging technology, flip-chip chip-scale package (FCCSP) packaging technology, low profile quad-flat package/quad-flat no-leads (LQFP/QFN) packaging technology, plastic ball grid array/thermally enhanced ball grid array (P'TEBGA) packaging technology, fine ball grid array (FBGA) packaging technology, fan-out wafer-level package/panel-level packaging (FOWLP/PLP) packaging technology, and wire bonded (WB) packaging technology.

As illustrated in the diagrams 700 and 800, recent developments in SoC packaging technology can allow, for example, systems to be incorporated into a package, antennas to be incorporated into a package, radio frequency devices to be incorporated into a package, and photonic devices to be incorporated into a package. With reference to FIGS. 3-6, advantageously, such recent developments can allow the apparatus 300 to be incorporated into an SoC package that includes one or more of the light-emitting diode 308, the antenna 310, the quantum material 312, the photodetector 314, the transparent material interface 316, the light confinement system 342, the light pipe 344, the controller 508, or the microwave source 512.

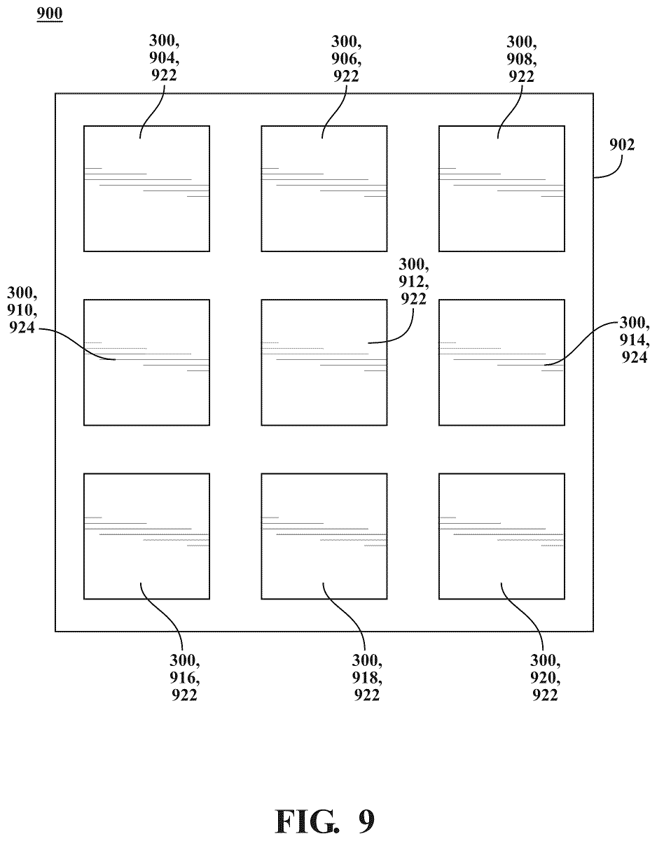

FIG. 9 includes a diagram that illustrates an example of an array of sensors 900, according to the disclosed technologies. For example, the apparatus 300 can include a plurality of apparatuses 300. For example, the plurality of apparatuses 300 can include the array of sensors 900. For example, a sensor, of the array of sensors 900, can be disposed at a corresponding position within a two-dimensional closed curve 902. For example, the array of sensors 900 can be configured to produce a map of measurements of the physical condition at positions within the two-dimensional closed curve 902. For example, the array of sensors 900 can include: a first sensor 904, a second sensor 906, a third sensor 908, a fourth sensor 910, a fifth sensor 912, a sixth sensor 914, a seventh sensor 916, an eighth sensor 918, and a ninth sensor 920.

For example, in an implementation, the array of sensors 900 can include a first set of sensors 922 and a second set of sensors 924. For example, the first set of sensors 922 can include: the first sensor 904, the second sensor 906, the third sensor 908, the fifth sensor 912, the seventh sensor 916, the eighth sensor 918, and the ninth sensor 920. For example, each sensor of the first set of sensors 922 can: (1) have a light-emitting diode, an antenna, a quantum material, and a photodetector and (2) be configured to determine a measurement of a first physical condition. For example, the second set of sensors 924 can include: the fourth sensor 910 and the sixth sensor 914. For example, each sensor of the second set of sensors 924 can: (1) have a light-emitting diode, an antenna, a quantum material, and a photodetector and (2) be configured to determine a measurement of a second physical condition.

For example: (1) the first physical condition can include one or more of: (a) a strength of a magnetic field in an environment of the first set of sensors 922, (b) a temperature of the environment of the first set of sensors 922, or (c) a mechanical strain of an object in the environment of the first set of sensors 922, (2) the second physical condition can include one or more of: (a) a strength of the magnetic field in an environment of the second set of sensors 924, (b) a temperature of the environment of the second set of sensors 924, or (c) a mechanical strain of an object in the environment of the second set of sensors 924, and (3) the second physical condition can be different from the first physical condition.

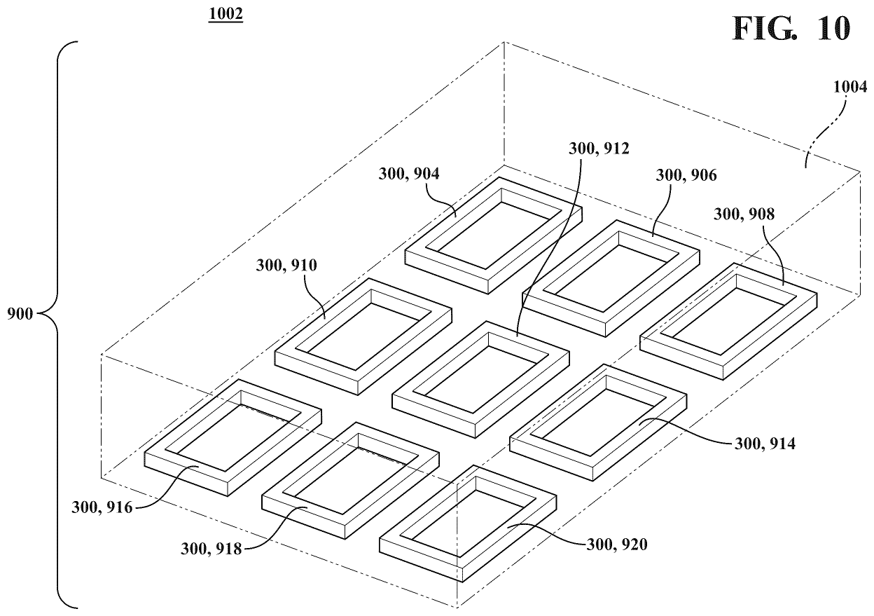

FIG. 10 includes a diagram that illustrates a first example 1002 of an SoC package 1004 of the array of sensors 900, according to the disclosed technologies. As described above, the array of sensors 900 can include, for example, a plurality of apparatuses 300. For example, an apparatus 300, of the plurality of apparatuses 300, can be an SoC integrated circuit and include an SoC package. In turn, in the first example 1002, the array of sensors 900 can include the SoC package 1004 that includes the several sensors of the array of sensors 900. With reference to FIGS. 3-8, the recent developments in SoC packaging technology can allow, for example, the apparatus 300 to be incorporated into an SoC package that includes one or more of the light-emitting diode 308, the antenna 310, the quantum material 312, the photodetector 314, the transparent material interface 316, the light confinement system 342, the light pipe 344, the controller 508, or the microwave source 512 so that the apparatus 300 can be configured as an independent device. Returning to FIG. 10, advantageously, according to the first example 1002, this can allow the SoC package 1004 of the array of sensors 900 to be realized using a packaging technology that is less sophisticated than a packaging technology used for the SoC package of the apparatus 300. Advantageously, for example, this can simplify the manufacture of the array of sensors 900.

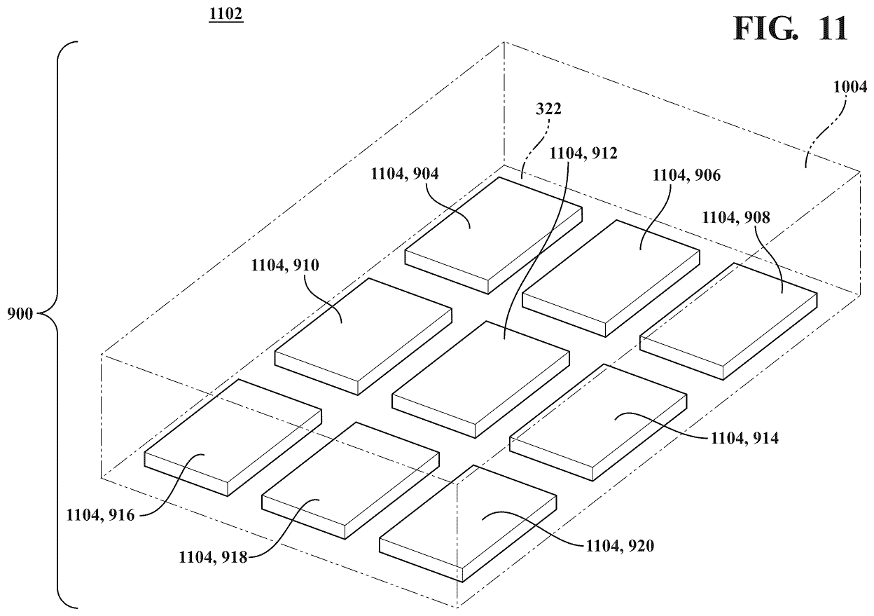

FIG. 11 includes a diagram that illustrates a second example 1102 of the SoC package 1004 of the array of sensors 900, according to the disclosed technologies. As described above, the apparatus 300 can include, for example, several devices that perform different functions but are all attached to the substrate 322 as a set of devices 1104. With reference to FIGS. 3-6 and 11, for example, the set of devices 1104 can include one or more of the light-emitting diode 308, the antenna 310, the quantum material 312, the photodetector 314, the transparent material interface 316, the light confinement system 342, the light pipe 344, the controller 508, or the microwave source 512. For example, the apparatus 300 can include the set of devices 1104. In the second example 1102, the array of sensors 900 can include a plurality of apparatuses 300 attached to the substrate 322. Advantageously, for example, having a plurality of sensors of the array of sensors 900 all attached to the substrate 322 can reduce an amount of material used for the SoC package 1004, which can reduce one or more of a profile or a form factor of the array of sensors 900, improve a performance of the array of sensors 900, or both.

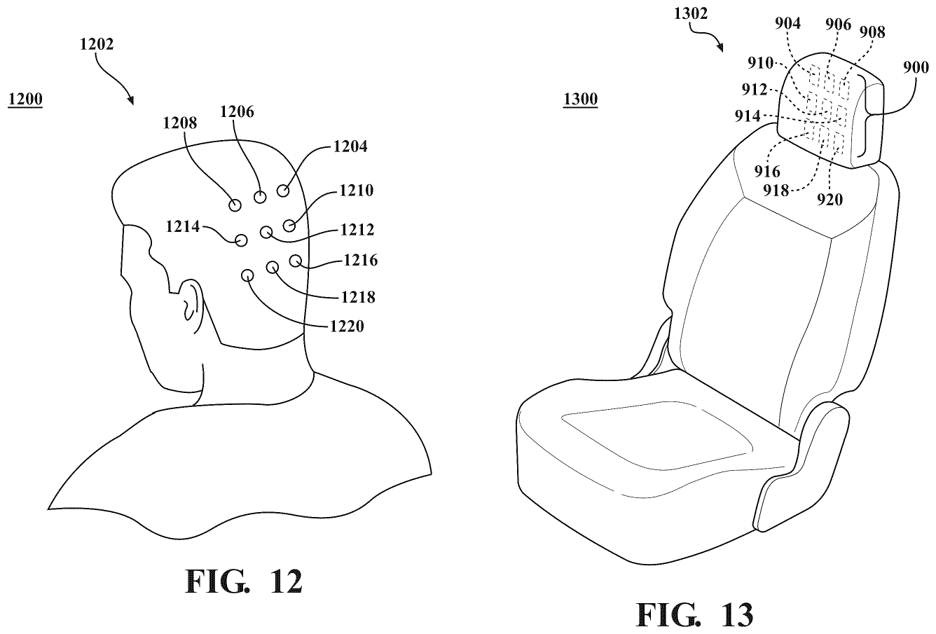

FIG. 12 includes a diagram that illustrates an example 1200 of positions, on a head 1202, at which measures of electrical activity of a brain (not illustrated) are obtained for an electroencephalogram (EEG). In the example 1200, the positions can include: a first position 1204, a second position 1206, a third position 1208, a fourth position 1210, a fifth position 1212, a sixth position 1214, a seventh position 1216, an eighth position 1218, and a ninth position 1220.

FIG. 13 includes a diagram that illustrates an example 1300 of the array of sensors 900 disposed upon a car seat 1302, according to the disclosed technologies. With reference to FIGS. 12 and 13, in the example 1300, a position of the first sensor 904 can correspond to the first position 1204, a position of the second sensor 906 can correspond to the second position 1206, a position of the third sensor 908 can correspond to the third position 1208, a position of the fourth sensor 910 can correspond to the fourth position 1210, a position of the fifth sensor 912 can correspond to the fifth position 1212, a position of the sixth sensor 914 can correspond to the sixth position 1214, a position of the seventh sensor 916 can correspond to the seventh position 1216, a position of the eighth sensor 918 can correspond to the eighth position 1218, and a position of the ninth sensor 920 can correspond to the ninth position 1220. In the example 1300, the array of sensors 900 can be configured to measure a strength of a magnetic field in an environment of the brain for an analysis similar to an analysis associated with an EEG.

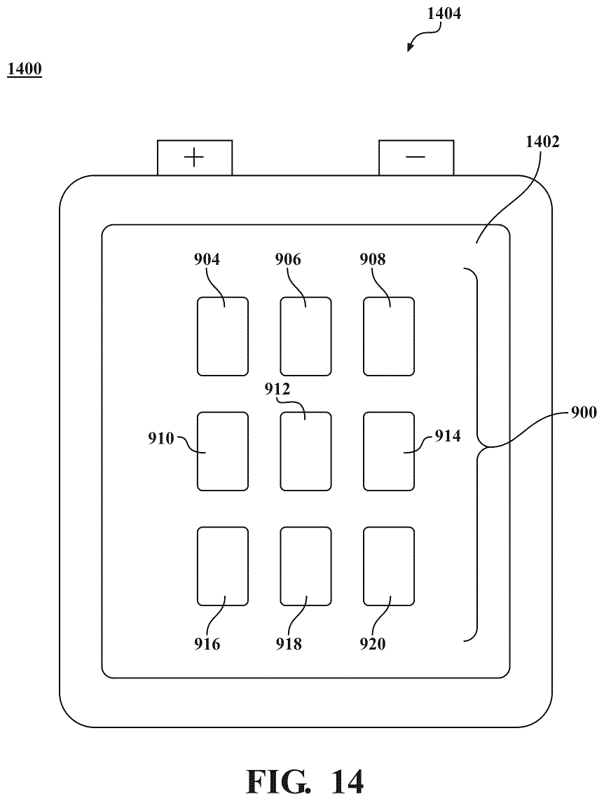

FIG. 14 includes a diagram that illustrates an example 1400 of the array of sensors 900 disposed upon a surface 1402 of a pouch cell 1404, according to the disclosed technologies. For example, the pouch cell 1404 can be a type of battery with a flexible, flat, pouch-like design. In the example 1400, the array of sensors 900 can be configured to measure a physical condition (e.g., a strength of a magnetic field or a temperature) of the surface 1402 to detect a possible defect in the pouch cell 1404.

Detailed embodiments are disclosed herein. However, one of skill in the art understands, in light of the description herein, that the disclosed embodiments are intended only as examples. Therefore, specific structural and functional details disclosed herein are not to be interpreted as limiting, but merely as a basis for the claims and as a representative basis for teaching one of skill in the art to variously employ the aspects herein in virtually any appropriately detailed structure. Furthermore, the terms and phrases used herein are not intended to be limiting but rather to provide an understandable description of possible implementations. Various embodiments are illustrated in FIGS. 3-6, 9-11, 13, and 14, but the embodiments are not limited to the illustrated structure or application.

The flowchart and block diagrams in the figures illustrate the architecture, functionality, and operation of possible implementations of systems, methods, and computer program products according to various embodiments. In this regard, each block in flowcharts or block diagrams may represent a module, segment, or portion of code, which comprises one or more executable instructions for implementing the specified logical function(s). One of skill in the art understands, in light of the description herein, that, in some alternative implementations, the functions described in a block may occur out of the order depicted by the figures. For example, two blocks depicted in succession may, in fact, be executed substantially concurrently, or the blocks may be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suitable. A typical combination of hardware and software can be a processing system with computer-readable program code that, when loaded and executed, controls the processing system such that it carries out the methods described herein. The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product that comprises all the features enabling the implementation of the methods described herein and that, when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. As used herein, the phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples of the computer-readable storage medium would include, in a non-exhaustive list, the following: a portable computer diskette, a hard disk drive (HDD), a solid-state drive (SSD), a read-only memory (ROM), an erasable programmable read-only memory (EPROM or flash memory), a portable compact disc read-only memory (CD-ROM), a digital versatile disc (DVD), an optical storage device, a magnetic storage device, or any suitable combination of the foregoing. As used herein, a computer-readable storage medium may be any tangible medium that can contain or store a program for use by or in connection with an instruction execution system, apparatus, or device.

Generally, modules, as used herein, include routines, programs, objects, components, data structures, and so on that perform particular tasks or implement particular data types. In further aspects, a memory generally stores such modules. The memory associated with a module may be a buffer or may be cache embedded within a processor, a random-access memory (RAM), a ROM, a flash memory, or another suitable electronic storage medium. In still further aspects, a module as used herein, may be implemented as an application-specific integrated circuit (ASIC), a hardware component of a system on a chip (SoC), a programmable logic array (PLA), or another suitable hardware component (e.g., a central processing unit (CPU), a graphics processing unit (GPU), a field-programmable gate array (FPGA), or the like) that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the disclosed technologies may be written in any combination of one or more programming languages, including an object-oriented programming language such as Java™, Smalltalk, C++, or the like, and conventional procedural programming languages such as the “C” programming language or similar programming languages. The program code may execute entirely on a user's computer, partly on a user's computer, as a stand-alone software package, partly on a user's computer and partly on a remote computer, or entirely on a remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of. or. ” as used herein refers to and encompasses any and all possible combinations of one or more of the associated listed items. For example, the phrase “at least one of A, B, or C” includes A only, B only, C only, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. An apparatus, comprising:
a light-emitting diode;
an antenna configured to emit an electromagnetic signal that sweeps through a range of frequencies;
a quantum material;
a photodetector configured to determine an amplitude of a wavelength of a light emitted by the quantum material, the amplitude being a function of a frequency, within the range, and a measurement of a physical condition; and
a transparent material interface made of a transparent epoxy and configured to convey the light:
from the light-emitting diode to the quantum material, and
from the quantum material to the photodetector.

2. The apparatus of claim 1, wherein the apparatus comprises a system-on-a-chip package.

3. The apparatus of claim 1:
further comprising a substrate:
to which the light-emitting diode, the antenna, and the photodetector are attached, and
upon which at least a portion of the transparent epoxy is deposited,
wherein the at least the portion of the transparent epoxy forms a transparent material interface defined by a two-dimensional closed curve on a plane of the substrate.

4. The apparatus of claim 3, wherein the quantum material is attached to the photodetector by another portion of the transparent epoxy.

5. The apparatus of claim 3, wherein the quantum material is attached to the substrate and is disposed between the light-emitting diode and the photodetector.

6. The apparatus of claim 3, wherein:
a first portion of the antenna is in proximity to the quantum material and is inside of the two-dimensional closed curve, and
a second portion of the antenna is outside of the two-dimensional closed curve.

7. The apparatus of claim 3:
wherein the substrate comprises a semiconductor chip with sidewalls, and
further comprising an opaque epoxy deposited on the semiconductor chip in a manner that forms a light confinement system configured to keep the light within the apparatus.

8. The apparatus of claim 3, further comprising a light pipe disposed between the light-emitting diode and the quantum material and configured to convey the light from the light-emitting diode to the quantum material.

9. The apparatus of claim 1, wherein:
the photodetector is included in an integrated circuit,
the integrated circuit further comprises a filter, and
the filter is disposed between the quantum material and the photodetector and is configured to filter a wavelength of the light produced by the light-emitting diode.

10. The apparatus of claim 1:
wherein:
the light-emitting diode is included in a first integrated circuit, and
the photodetector is included in a second integrated circuit, and
further comprising a substrate to which the first integrated circuit and the second integrated circuit are attached.

11. The apparatus of claim 10, wherein:
the quantum material is included in a third integrated circuit, and
the third integrated circuit is attached to the substrate.

12. The apparatus of claim 1, wherein:
the apparatus comprises a plurality of apparatuses, and
the plurality of apparatuses comprises an array of sensors.

13. The apparatus of claim 12, wherein:
a sensor, of the array of sensors, is disposed at a corresponding position within a two-dimensional closed curve, and
the array of sensors is configured to produce a map of measurements of the physical condition at positions within the two-dimensional closed curve.

14. An apparatus, comprising:
a first integrated circuit, attached to a substrate, that includes a light-emitting diode;
an antenna attached to the substrate and configured to emit an electromagnetic signal that sweeps through a range of frequencies;
a quantum material; and
a second integrated circuit, attached to the substrate, that includes a photodetector configured to determine an amplitude of a wavelength of a light emitted by the quantum material, the amplitude being a function of a frequency, within the range, and a measurement of a physical condition.

15. The apparatus for claim 14, wherein the antenna has a spiral shape and surrounds the quantum material.

16. The apparatus of claim 14, further comprising a controller attached to the substrate, electronically communicably coupled to the first integrated circuit and the second integrated circuit, and configured to control an operation of the light-emitting diode and to determine the measurement of the physical condition.

17. The apparatus of claim 16:
further comprising a microwave source attached to the substrate, electronically communicably coupled to the controller, and configured to produce the electromagnetic signal,
wherein the controller is further configured to cause the microwave source to produce the electromagnetic signal in a manner that includes a sweep through the range of frequencies.

18. An array of sensors, comprising:
a first set of sensors, wherein each sensor of the first set of sensors:
has a light-emitting diode, an antenna, a quantum material, and a photodetector, and
is configured to determine a measurement of a first physical condition; and
a second set of sensors, wherein each sensor of the second set of sensors:
has a light-emitting diode, an antenna, a quantum material, and a photodetector, and
is configured to determine a measurement of a second physical condition.

19. The array of sensors of claim 18, wherein the array of sensors comprises a system-on-a-chip package.

20. The array of sensors of claim 18, wherein:
the first physical condition comprises at least one of:
a strength of a magnetic field in an environment of the first set of sensors,
a temperature of the environment of the first set of sensors, or
a mechanical strain of an object in the environment of the first set of sensors,
the second physical condition comprises at least one of:
a strength of the magnetic field in an environment of the second set of sensors,
a temperature of the environment of the second set of sensors, or
a mechanical strain of an object in the environment of the second set of sensors, and
the second physical condition is different from the first physical condition.
